(19) United States
(12) Patent Application Publication
(10) Pub. No.: US 2010/0309632 A1
(43) Pub. Date: Dec. 9, 2010

(54) MOTHERBOARD WITH MOUNTING HOLES

(75) Inventor: QI-JIE CHEN, Shenzhen City (CN)

Correspondence Address: Altis Law Group, Inc.;ATTN: Steven Reiss, 288 SOUTH MAYO AVENUE, CITY OF INDUSTRY, CA, 91789, US

(73) Assignees: HONG FU JIN PRECISION INDUSTRY (ShenZhen) CO.LTD., Shenzhen City (CN); HON HAI PRECISION INDUSTRY CO., LTD., Tu-Cheng (TW)

(21) Appl. No.: 12/556,387

(22) Filed: Sep. 9, 2009

(30) Foreign Application Priority Data
Jun. 5, 2009 (CN) 200910302953.2

(51) Int. Cl. H05K 7/20

(52) U.S. Cl. 361/709

(57) ABSTRACT

A motherboard includes a printed circuit board, and a heat generating component mounted on the printed circuit board. A plurality of mounting holes is defined in the printed circuit board for mounting a heat sink apparatus on the heat generating component. At least a ground via is defined in the printed circuit board and adjacent to each of the mounting holes. The heat sink apparatus is capable of electrically contacting the ground via, and the ground via is capable of reducing electromagnetic interference of the motherboard and grounding static electricity on the heat sink apparatus.

### BACKGROUND

1. Technical Field

The present disclosure relates to motherboards, and more particularly to a motherboard with mounting holes defined therein.

2. Description of Related Art

A central processing unit (CPU) of a motherboard generates a lot of heat during use. Thus, it is necessary to attach a heat sink apparatus on the CPU chip to dissipate the heat and to prevent the CPU from overheating.

There are usually four mounting holes defined in the motherboard adjacent to the CPU socket. Four screws attached to the heat sink apparatus are inserted in the mounting holes when the heat sink apparatus is mounted on the motherboard. Then the heat sink apparatus is capable of dissipating the heat generated by the CPU. However, the typical motherboard also generates much electromagnetic interference (EMI), and static electricity on the heat sink apparatus.

Therefore, an improved motherboard to overcome the above-mentioned problem is desired.

### BRIEF DESCRIPTION OF THE DRAWINGS

FIG. 1 is an illustrated view of heat sink adapted to be installed on a motherboard;

FIG. 2 is an illustrated view of a motherboard with mounting holes in accordance with an embodiment of the present disclosure;

FIG. 3 is a sectional view taken along line II-II in FIG. 2; and

FIG. 4 is an illustrated view of a multi-layer printed circuit board (PCB).

### DETAILED DESCRIPTION

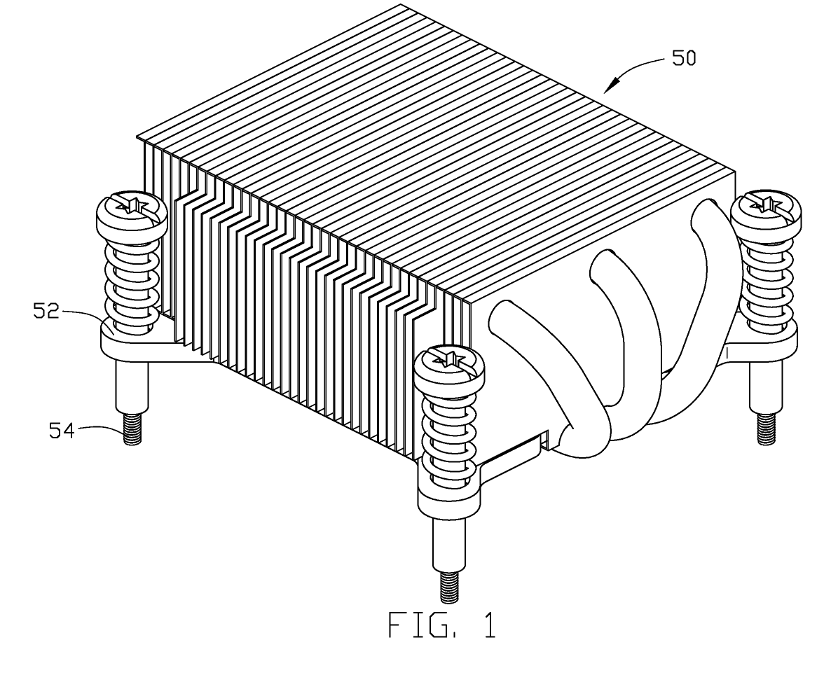

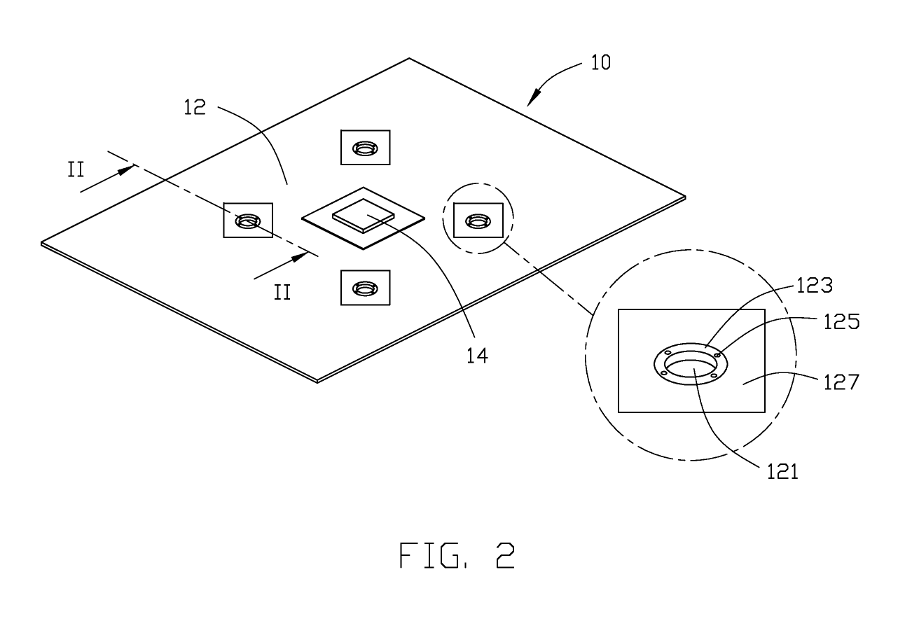

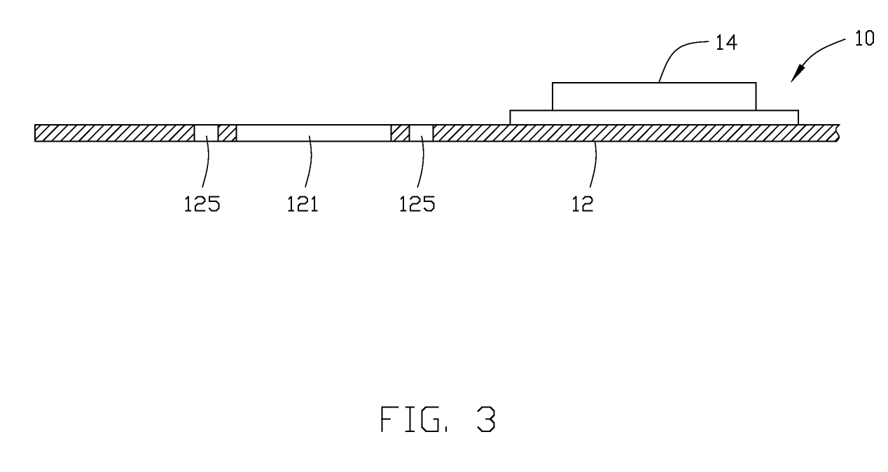

Referring to FIGS. 1-3 an embodiment of a motherboard 10 includes a printed circuit board (PCB) 12 and a heat generating component 14, such as a CPU chip, mounted onto the printed circuit board 12. Four mounting holes 121 are defined in the PCB 12 for mounting a heat sink apparatus 50 on the heat generating component 14. The heat sink apparatus 50 has four protruding pieces 52. Each of the protruding pieces 52 has a screw 54 attached thereto. The screws 54 are screwably engagable with the mounting holes 121 of the PCB 12 respectively.

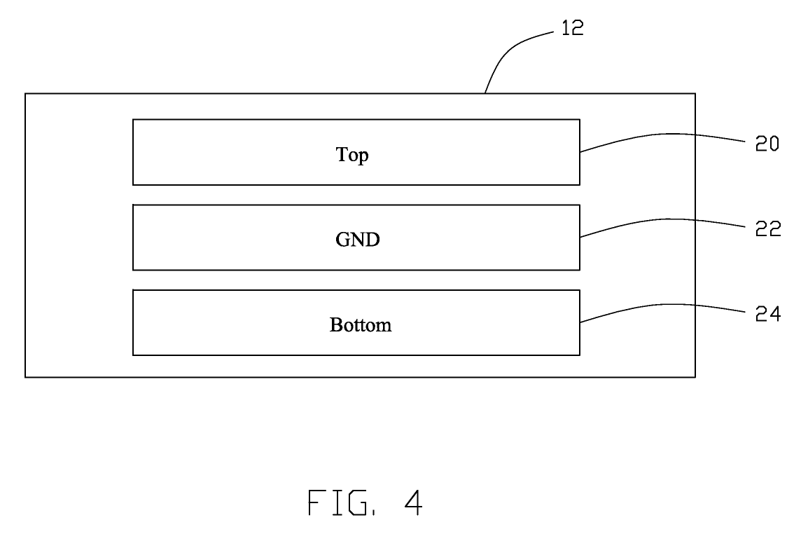

A ring-shaped region 123 is defined around each of the mounting holes 121, and coated with copper. Four ground vias 125 are defined in the PCB 12, and respectively extend through the ring regions 123. The PCB 12 includes a top layer 20, a bottom layer 24, and at least a ground layer 22 between the top layer 20 and the bottom layer 24 (See FIG. 4). Surfaces of the ground vias 125 are plated with electrically conductive material, and electrically conduct to the ground layer. One skilled in the art will appreciate that the ground vias 125 are important to both EMI/EMC (electromagnetic interference/electromagnetic compatibility) and SI (signal integration) performance for high-speed signals. In the embodiment, the ground vias 125 can reduce EMI and also grounds static electricity on the heat sink apparatus 50.

An isolation region 127 is formed on the PCB 12 around each ring region 123 of the mounting hole 121. The isolation regions 127 are coated with an isolation material such as grease. In this embodiment, the isolation regions 127 are rectangular-shaped.

In the embodiment, a difference between an inner diameter and an outer diameter of the ring regions 123 is greater than the diameter of the ground vias 125.

When the heat sink apparatus 50 is mounted on the PCB 12, the screws 54 of the heat sink apparatus 50 engage with the mounting holes 121 and resist against the ring regions 123 of the mounting holes 121 of the PCB 12. Thus, the heats sink apparatus 50 is electrically connected with the ground vias 125, and the ground vias 125 reduce electromagnetic interference of the motherboard and ground the static electricity on the heat sink apparatus.

While the present invention has been illustrated by the description of preferred embodiments thereof, and while the preferred embodiments have been described in considerable detail, it is not intended to restrict or in any way limit the scope of the appended claims to such details. Additional advantages and modifications within the spirit and scope of the present invention will readily appear to those skilled in the art. Therefore, the present invention is not limited to the specific details and illustrative examples shown and described.

What is claimed is:

1. A motherboard, comprising:
a printed circuit board;
a heat generating component mounted on the printed circuit board;
a plurality of mounting holes defined in the printed circuit board for mounting a heat sink apparatus onto the heat generating component; and
at least a ground via defined in the printed circuit board and adjacent to each of the mounting holes;
wherein the heat sink apparatus electrically contacts the ground via, and the ground via reduces electromagnetic interference of the motherboard and grounds static electricity on the heat sink apparatus.

2. The motherboard of claim 1, wherein the printed circuit board comprises a top layer, a bottom layer, and at least a ground layer between the top layer and the bottom layer.

3. The motherboard of claim 2 wherein each of the mounting holes comprises a ring region that is coated with copper, the ground via is perpendicularly defined through the ring region.

4. The motherboard of claim 3, wherein a difference between an inner diameter and an outer diameter of the copper ring is greater than a diameter of the ground via.

5. The motherboard of claim 4, wherein an isolation region is formed on the printed circuit board and around each of the mounting holes, the isolation region is covered with insulation material.

6. The motherboard of claim 1, wherein there are four ground via defined in the printed circuit board and around each of the mounting holes.

7. A motherboard comprising:
a printed circuit board with a heat generating component and a heat sink apparatus mounted thereon;
at least a mounting hole defined in the printed circuit board for receiving screws extending from the heat sink apparatus; and
at least a ground via defined in the printed circuit board and adjacent to each of the mounting holes, the ground via capable of reducing electromagnetic interference of the motherboard and grounds static electricity on the heat sink apparatus.

8. The motherboard of claim 7, wherein each of the mounting holes comprises a ring region that is coated with copper, the ground via is perpendicularly defined through the ring region.

9. The motherboard of claim 8, wherein a difference between an inner diameter and an outer diameter of the ring region is greater than a diameter of the ground via.

10. The motherboard of claim 7, wherein an isolation region is formed on the printed circuit board and around the ring region, the isolation region is covered with insulation material.

11. The motherboard of claim 10, wherein the isolation region is rectangular-shaped.
